(19) United States
(12) Patent Application Publication
(10) Pub. No.: US 2024/0240304 A1
(43) Pub. Date: Jul. 18, 2024

(54) METAL OXY-FLUORIDE COATING FOR CHAMBER COMPONENTS AND METHOD OF COATING THEREOF

(71) Applicant: Applied Materials, Inc., Santa Clara, CA (US)

(72) Inventors: David Jorgensen, Santa Clara, CA (US); David Soltz, Santa Clara, CA (US)

(21) Appl. No.: 18/537,234

(22) Filed: Dec. 12, 2023

Related U.S. Application Data
(60) Provisional application No. 63/438,848, filed on Jan. 13, 2023.

(51) Int. Cl. C23C 14/08; C23C 14/06; C23C 14/54

(52) U.S. Cl. CPC C23C 14/083; C23C 14/0694; C23C 14/548

(57) ABSTRACT

Described herein is a chamber component including a metal oxy-fluoride coating including YF₃, ZrF₄ or combination thereof and a metal oxide consisting of Y₂O₃ and ZrO₂. The metal oxy-fluoride coating includes 5 mol % to 90 mol % of YF₃ or ZrF₄ and 10 mol % to 95 mol % of the metal oxide. The metal oxy-fluoride coating is amorphous and has:

$$35 - 50 at . \% of yttrium ( Y ) ;$$

$$0.3 - 10 at . \% of zirconium ( Zr ) ;$$

$$5 - 57 at . \% of oxygen ( O ) ; and$$

$$3 - 65 at . \% of fluorine ( F ) .$$

### CROSS REFERENCE TO RELATED APPLICATION(S)

The present application claims priority to U.S. Provisional Patent Application No. 63/438,848 filed on Jan. 13, 2023, the contents of which are incorporated in its entirety.

### TECHNICAL FIELD

Embodiments of the present disclosure relate, in general, to methods of coating an article, where the coating includes a metal oxy-fluoride. The present disclosures also relates to a coating including a metal oxy-fluoride, wherein the coating is amorphous.

### BACKGROUND

Various manufacturing processes expose chamber components and their coating materials to high temperatures, high energy plasma, a mixture of corrosive gases, high stress, and combinations thereof. Rare earth oxides are frequently used in chamber component manufacturing due to their resistance to erosion from plasma etch chemistries. However, exposure of rare earth oxides to fluorine based plasma can cause cracking and shedding of particles onto wafers.

Furthermore, oxide coatings such as Y₂O₃ are permeable to water and can cause the adsorption of water. As a result, exposure of oxide coatings such as Y₂O₃ coatings to air generally causes a brittle M(OH) layer (e.g., a Y(OH)₃ layer) to form at a surface of the oxide coating, where M is a metal. Tests have shown the presence of multiple —OH groups at the surface of Y₂O₃ coatings exposed to air. The M(OH) layer is brittle and can shed particles onto processed wafers. Additionally, the M(OH) layer causes increased leakage current in the metal oxide coating (e.g., in the Y₂O₃ coating).

In some instances YF₃ has been used as a coating for chamber components. Use of the YF₃ coating can mitigate the issue of yttrium based particles on processed wafers. However, applying a YF₃ coating to chamber components of an etch reactor has been shown to cause a significant etch rate drop (e.g., an etch rate drop of as much as 60%), process drift and chamber matching issues.

### SUMMARY

In one embodiment a method is provided. The method includes providing a metal oxy-fluoride source material including YF₃, ZrF₄ or combination thereof and a metal oxide consisting of yttrium oxide (Y₂O₃) and zirconium oxide (ZrO₂), wherein the metal oxy-fluoride source material includes about 5 mol % to about 90 mol % of YF₃, ZrF₄ or combination thereof and about 10 mol % to about 95 mol % of the metal oxide. The method also includes performing one of a vapor deposition, sputtered deposition or evaporated deposition of the metal oxy-fluoride source material to form a metal oxy-fluoride coating on an article. The metal oxy-fluoride coating having:

$$about 35 - 50 at . \% of yttrium ( Y ) ;$$

$$about 0.3 - 10 at . \% of zirconium ( Zr ) ;$$

$$about 5 - 57 at . \% of oxygen ( O ) ; and$$

$$about 3 - 65 at . \% of fluorine ( F ) ;$$

The metal oxy-fluoride coating that is formed is amorphous.

In another embodiment, a thin film is provided. The thin film includes a metal oxy-fluoride having:

$$35 - 50 at . \% of yttrium ( Y ) ;$$

$$0.3 - 10 at . \% of zirconium ( Zr ) ;$$

$$5 - 57 at . \% of oxygen ( O ) ; and$$

$$3 - 65 at . \% of fluorine ( F ) ;$$

and is amorphous.

In another embodiment, a process is provided. The process includes depositing a metal oxy-fluoride coating on a surface of a chamber component. The metal oxy-fluoride coating includes yttrium fluoride (YF₃), zirconium fluoride (ZrF₄), or combination thereof and a metal oxide consisting of yttrium oxide (Y₂O₃) and zirconium oxide (ZrO₂) having about 5 mol % to about 90 mol % YF₃ or ZrF₄ and about 10 mol % to about 95 mol % of the metal oxide, wherein the metal oxy-fluoride coating is amorphous.

In yet another embodiment, a method is provided. The method includes providing a metal fluoride source material including YF₃, ZrF₄, or a combination thereof, and a metal oxide source material consisting of yttrium oxide (Y₂O₃) and zirconium oxide (ZrO₂), wherein the metal oxide source material includes about 0.1 mol % to about 20 mol % of ZrO₂. The method also includes performing one of a vapor deposition, sputtered deposition or evaporated deposition of the metal fluoride source material while concurrently and independently performing one of a vapor deposition, sputtered deposition or evaporated deposition of the metal oxide source material to form a metal oxy-fluoride coating on an article. The respective evaporation and deposition rates from the metal fluoride source material and the metal oxide source material may produce a metal oxy-fluoride coating having:

$$about 35 - 50 at . \% of yttrium ( Y ) ;$$

$$about 0.3 - 10 at . \% of zirconium ( Zr ) ;$$

$$about 5 - 57 at . \% of oxygen ( O ) ; and$$

$$about 3 - 65 at . \% of fluorine ( F ) ;$$

The metal oxy-fluoride coating that is formed is amorphous.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2 illustrates a process for forming a M-O—F layer at a surface of a metal oxide coating according to an embodiment.

FIG. 3 illustrates a cross sectional side view of a chamber component that includes a M-O—F layer according to an embodiment.

FIG. 4 illustrates an example architecture of a manufacturing system.

### DETAILED DESCRIPTION OF EMBODIMENTS

Embodiments disclosed herein describe coated articles, coated chamber components, methods of coating articles and chamber components, methods of reducing or eliminating defects from semiconductor processing chambers, and methods of using coated articles and chamber components and processing chambers containing coated chamber components. To reduce reactions between component materials and reactive chemicals and/or plasmas, which form particles and other trace metal contaminates, a coating is included on the article and/or chamber component. The coating may also reduce any defects and increase seasoning time of the article and/or chamber component. The coating may be or include a metal oxy-fluoride layer, where the metal may include a combination of yttrium (Y) and zirconium (Zr). It has been found that when the coating is in an amorphous state, defects are reduced and the amorphous state aids in plasma resistance during chemical and etch processes. The inventors have found that when oxygen is incorporated with fluorides of either Y or Zr or both, then crystallization is frustrated, allowing an amorphous state to form.

In previous approaches to coating an article or chamber component, yttrium oxide and yttrium-zirconium binary oxide compositions have been used without fluorine. These compositions had a slow seasoning time, and increase particle defects on processed substrates (e.g., on a wafer). The coating of the present disclosure was found to have a faster seasoning time and decrease in particle defects when oxides of Y and Zr were combined with fluorides of Y or Zr or both. Thus, embodiments improve the lifespan of chamber components by using a coating that is more amorphous to protect the chamber component from the corrosive environments of the plasma processes. Y—Zr—O—F coatings and layers are highly resistant to erosion and corrosion by fluorine-based plasmas. Additionally, Y—Zr—O—F coatings are generally resistant to fluorination by fluorine-based plasmas. As a result of these properties, Y—Zr—O—F coatings and layers as described herein offer significant reduction in particles, improve wafer process throughput, process stability and also improve etch rate uniformity and chamber to chamber uniformity when used on chamber components for processing chambers.

Also, in previous approaches to coating an article or chamber component, there are two main failure mechanisms of the coatings in the field. In the first failure mechanism, the etch rate of the processing chamber will affect the life of the coated chamber component or coated article. Thus, the etch rate will cause the coating to eventually wear through. In the second failure mechanism, during processing reaction products can be created and build up on the coating of the chamber component or article. These reaction products may shed from the coating and cause particle contaminants and/or may alter a chamber processing chemistry, which may affect, for example, the etch rate on the wafer. Therefore, the coating of any chamber component should be able to withstand various etch rates and avoid the buildup of reaction products on the chamber component. To achieve this, the inventors have found that when the coating is in an amorphous state, it wears more slowly, has a lower etch rate and is more resistant to the reaction products than a coating in a crystalline state.

It has been found that providing a metal oxy-fluoride coating in an amorphous state reduces defects during etch processes. Additionally, this coating may provide chemical and/or etch resistance in plasma environments. The metal oxy-fluoride coating may include a combination of YF₃, ZrF₄ and Y₂O₃—ZrO₂ and when applied to a surface is in an amorphous state. This combination in the coating was found to have a faster in-chamber seasoning time to reach a stable on-wafer etch rate when compared to Y₂O₃ or Y₂O₃—ZrO₂ oxide compositions. Further, the metal oxy-fluoride coating of the present disclosure was found to have better chemical resistance than Y₂O₃, YAG or YF₃, which produced fewer particle defects on chamber components, such as a wafer. Additionally, the metal oxy-fluoride coating has a higher density and is more amorphous than Y₂O₃ or Y₂O₃—ZrO₂ oxide compositions, allowing for faster seasoning time and less/slower drift during use.

In embodiments disclosed herein a coating method is provided. The method includes providing a metal oxy-fluoride source material including YF₃, ZrF₄ or combination thereof and a metal oxide including yttrium oxide (Y₂O₃) and zirconium oxide (ZrO₂). In some embodiments, the metal oxy-fluoride source material includes about 5 mol % to about 90 mol % of YF₃, ZrF₄ or combination thereof and about 10 mol % to about 95 mol % of the metal oxide. The method further includes performing one of a vapor deposition, sputtered deposition or evaporated deposition of the metal oxy-fluoride source material to form a metal oxy-fluoride coating on an article. The metal oxy-fluoride coating may have about 35-50 at. % of yttrium (Y); about 0.3-10 at. % of zirconium (Zr); about 5-57 at. % of oxygen (O); and about 3-65 at. % of fluorine (F). The metal oxy-fluoride coating is amorphous in embodiments. When the coating is amorphous, a denser coating may be formed that may limit the surface area that could be fluorinated or react with a chamber environment during a process of the processing chamber. Thus, the coating may allow the chamber component or article to season and reach equilibrium with the process at a faster rate than a crystalline coating.

Without being bound to a particular theory, to achieve an amorphous state, the addition of fluorine to a metal oxide aids in the amorphization of the coating by frustrating the crystal structure during condensation and crystallization during the coating process. The thermodynamically stable crystal structures of metal oxy-fluorides are more complex and have a higher degree of required atom ordering than the cubic crystal structures of the metal oxides Y₂O₃ or ZrO₂. The complex crystal structures are kinetically unfavorable during coating physical vapor deposition and are therefore inhibited in favor of the uncrystallized, or amorphous, state.

In some embodiments, the metal oxy-fluoride coating may be formed via atmospheric pressure plasma spray (APPS), low pressure plasma spray (LPPS), suspension plasma spray (SPS), ion assisted deposition (IAD), chemical vapor deposition (CVD), atomic layer deposition (ALD), magnetron sputtering physical vapor deposition (MSPVD), plasma enhanced chemical vapor deposition (PECVD), plasma enhanced atomic layer deposition (PEALD), or another deposition technique. In some embodiments, a bulk metal oxy-fluoride material is formed via hot pressing, cold pressing, spark plasma sintering, reverse co-precipitation, or similar processes. The bulk metal oxy-fluoride material may be used for a ceramic article (e.g., for a nozzle, lid, chamber liner, etc.). The bulk metal oxy-fluoride material may also be bonded to a chamber component, such as using diffusion bonding or metal bonding. In such an embodiment, the bulk metal oxy-fluoride material may be used as a protective layer on the chamber component.

In some embodiments, the metal oxy-fluoride source material may include about 50 mol % of YF₃, ZrF₄ or combination thereof and about 50 mol % of the metal oxide. In another embodiment, the metal oxy-fluoride source material includes about 90 mol % of YF₃, ZrF₄ or combination thereof and about 10 mol % of the metal oxide. In yet another embodiment, the metal oxy-fluoride source material includes about 5 mol % of YF₃, ZrF₄ or combination thereof and about 95 mol % of the metal oxide. In some embodiments, the metal oxy-fluoride source material may include about 5 mol %, about 10 mol %, about 15 mol %, about 20 mol %, about 25 mol %, about 50 mol %, about 75 mol %, about 80 mol %, about 85 mol %, about 90 mol %, or about 95 mol % of YF₃, ZrF₄ or combination thereof about 5 mol %, about 10 mol %, about 15 mol %, about 20 mol %, about 25 mol %, about 50 mol %, about 75 mol %, about 80 mol %, about 85 mol %, about 90 mol %, or about 95 mol % of a metal oxide.

In some embodiments, the metal oxide may include Y₂O₃ and ZrO₂. In some embodiments, the Y₂O₃ may be included at about 80%, about 85%, about 90% or about 95% based on total mole percent of the metal oxide. In some embodiments, the ZrO₂ may be included at about 2%, about 5%, about 10%, about 15%, or about 20% based on total mole percent of the metal oxide.

In some embodiments, the metal oxy-fluoride source may include about 50 mol % of YF₃ or ZrF₄ and about 50 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide. In another embodiment, the metal oxy-fluoride source may include about 90 mol % of YF₃, ZrF₄ or combination thereof and about 10 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide. In yet another embodiment, the metal oxy-fluoride source may include about 5 mol % of YF₃, ZrF₄ or combination thereof and about 95 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide.

In some embodiments, the article may include a semiconductor process chamber component or process chamber component for other manufacturing processes (e.g., for display, photovoltaics, etc.). Examples of process chamber components include a lid, a nozzle, a chuck (e.g., an electrostatic chuck), a chamber liner, a window, a heater, and so on.

In some embodiments, the metal oxy-fluoride coating consists of a Y—Zr—O—F layer.

In another embodiment of the present disclosure, a coating is provided. The coating may include a metal oxy-fluoride having about 35-50 at. % of yttrium (Y); about 0.3-10 at. % of zirconium (Zr); about 5-57 at. % of oxygen (O); and about 3-65 at. % of fluorine (F), wherein the coating is amorphous.

In some embodiments of the coating, the coating may coat at least one surface of a chamber component for semiconductor processing equipment.

In yet another embodiment of the present disclosure, a process is provided. The process may include forming a metal oxy-fluoride material on a surface of a chamber component, the metal oxy-fluoride material including yttrium fluoride (YF₃) or zirconium fluoride (ZrF₄) and a metal oxide consisting of yttrium oxide (Y₂O₃) and zirconium oxide (ZrO₂) having about 5 mol % to about 90 mol % of YF₃ and about 10 mol % to about 95 mol % of the metal oxide, wherein the metal oxy-fluoride material is amorphous.

In some embodiments, the process may further include heating the chamber component.

In some embodiments of the process, the metal oxy-fluoride material has about 35-50 at. % of yttrium (Y); about 0.3-10 at. % of zirconium (Zr); about 5-57 at. % of oxygen (O); and about 3-65 at. % of fluorine (F).

In some embodiments, the metal oxy-fluoride material may include about 50 mol % of YF₃, ZrF₄ or combination thereof and about 50 mol % of the metal oxide. In another embodiment, the metal oxy-fluoride material may include about 90 mol % of YF₃, ZrF₄ or combination thereof and about 10 mol % of the metal oxide. In yet another embodiment of the process, the metal oxy-fluoride material may include about 5 mol % of YF₃, ZrF₄ or combination thereof and about 95 mol % of the metal oxide.

In some embodiments of the process, forming the metal oxy-fluoride coating may include performing one of: performing a plasma spray process to deposit the metal oxy-fluoride coating; performing atomic layer deposition (ALD) to deposit the metal oxy-fluoride coating; performing ion assisted deposition (IAD) to deposit the metal oxy-fluoride coating; performing an air plasma spray process to deposit the metal oxy-fluoride coating; performing evaporation to deposit the metal oxy-fluoride coating; performing physical vapor deposition (PVD) or electron beam physical vapor deposition (EBPVD) to deposit the metal oxy-fluoride coating; performing a magnetron sputtering process to deposit the metal oxy-fluoride coating; or performing a suspension plasma spray process to deposit the metal oxy-fluoride coating.

In some embodiments, the metal oxy-fluoride material is a bulk material that may be used as a protective layer on a chamber component, or may be used as a chamber component itself. In such embodiments, forming the metal oxy-fluoride material may include performing a spark plasma sintering process to form the metal oxy-fluoride material; performing a hot pressing process to form the metal oxy-fluoride material; performing a cold isostatic pressing process to form the metal oxy-fluoride material; performing a reverse co-precipitation process to form the metal oxy-fluoride material.

In some embodiments of the process, the metal oxy-fluoride material (e.g., coating or layer) has a thickness of about 10 nm to about 300 μm.

In another embodiment of the present disclosure, a method is provided. The method may include providing a metal oxy-fluoride source material including YF₃, ZrF₄ or combination thereof and a metal oxide consisting of yttrium oxide (Y₂O₃) and zirconium oxide (ZrO₂), wherein the metal oxy-fluoride source material includes about 0.1 mol % to about 20 mol % of ZrO₂. The method may also include performing one of a vapor deposition, physical vapor deposition (PVD), electron beam physical vapor deposition (EBPVD), sputtered deposition or evaporated deposition of the metal oxy-fluoride source material to form a metal oxy-fluoride coating on an article. The metal oxy-fluoride coating having:

$$about 35 - 50 at . \% of yttrium ( Y ) ;$$

$$about 0.3 - 10 at . \% of zirconium ( Zr ) ;$$

$$about 5 - 57 at . \% of oxygen ( O ) ; and$$

$$about 3 - 65 at . \% of fluorine ( F ) ;$$

The metal oxy-fluoride coating that is formed is amorphous.

In some embodiments of the method, the metal oxy-fluoride source material may include about 50 mol % of YF₃, ZrF₄ or combination thereof and about 50 mol % of the metal oxide. In another embodiment, the metal oxy-fluoride source material includes about 90 mol % of YF₃, ZrF₄ or combination thereof and about 10 mol % of the metal oxide. In yet another embodiment, the metal oxy-fluoride source material includes about 5 mol % of YF₃, ZrF₄ or combination thereof and about 95 mol % of the metal oxide. In some embodiments, the metal oxy-fluoride source material may include about 5 mol %, about 10 mol %, about 15 mol %, about 20 mol %, about 25 mol %, about 50 mol %, about 75 mol %, about 80 mol %, about 85 mol %, about 90 mol %, or about 95 mol % of YF₃, ZrF₄ or combination thereof and about 5 mol %, about 10 mol %, about 15 mol %, about 20 mol %, about 25 mol %, about 50 mol %, about 75 mol %, about 80 mol %, about 85 mol %, about 90 mol %, or about 95 mol % of a metal oxide.

In some embodiments, the metal oxide may include Y₂O₃ and ZrO₂. In some embodiments, the Y₂O₃ may be included at about 80%, about 85%, about 90% or about 95% based on total mole percent of the metal oxide. In some embodiments, the ZrO₂ may be included at about 2%, about 5%, about 10%, about 15%, or about 20% based on total mole percent of the metal oxide.

In some embodiments, the metal oxy-fluoride source may include about 50 mol % of YF₃, ZrF₄ or combination thereof and about 50 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide. In another embodiment, the metal oxy-fluoride source may include about 90 mol % of YF₃, ZrF₄ or combination thereof and about 10 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide. In yet another embodiment, the metal oxy-fluoride source may include about 5 mol % of YF₃, ZrF₄ or combination thereof and about 95 mol % of the metal oxide. The metal oxide may include about 80%, about 85%, about 90%, or about 95% Y₂O₃ and about 2%, about 5%, about 10%, about 15%, or about 20% of ZrO₂, based on total mole percent of the metal oxide.

In some embodiments, the article may include a semiconductor process chamber component or process chamber component for other manufacturing processes (e.g., for display, photovoltaics, etc.). Examples of process chamber components include a lid, a nozzle, a chuck (e.g., an electrostatic chuck), a chamber liner, a window, a heater, and so on.

In some embodiments, the metal oxy-fluoride coating consists of a Y—Zr—O—F layer.

In some embodiments, a metal oxy-fluoride coating is formed via ion assisted deposition (IAD), atomic layer deposition (ALD), chemical vapor deposition (CVD), physical vapor deposition (PVD), electron beam physical vapor deposition (EBPVD), sputtered deposition or evaporated deposition or another deposition technique. The metal oxy-fluoride coating may be formed by combining a YF₃ and a metal oxide, such as yttrium oxide, zirconium oxide, or a combination thereof. The metal oxy-fluoride coating may be formed such that it is amorphous and does not have a crystalline structure. By having a coating with an amorphous structure, it is believed that it will limit the surface area that could possibly be reacted with the chamber environment and/or be fluorinated or oxidized. Therefore, the chamber component can be seasoned and reach equilibrium quicker than current coated chamber components.

The term “heat treating” is used herein to mean applying an elevated temperature to a ceramic article, such as by a furnace. “Plasma resistant material” refers to a material that is resistant to erosion and corrosion due to exposure to plasma processing conditions. The plasma processing conditions include a plasma generated from halogen-containing gases, such as C₂F₆, SF₆, SiCl₄, HBR, NF₃, CF₄, CHF₃, CH₂F₃, F, NF₃, Cl₂, CCl₄, BCl₃ and SiF₄, among others, and other gases such as O₂, or N₂O. The resistance of the material to plasma is measured through “etch rate” (ER), which may have units of Angstrom/min (k/min), throughout the duration of the coated components' operation and exposure to plasma. Plasma resistance may also be measured through an erosion rate having the units of nanometer/radio frequency hour (nm/RFHr), where one RFHr represents one hour of processing in plasma processing conditions. Measurements may be taken after different processing times. For example, measurements may be taken before processing, after 50 processing hours, after 150 processing hours, after 200 processing hours, and so on. An erosion rate lower than about 100 nm/RFHr is typical for a plasma resistant coating material. A single plasma resistant material may have multiple different plasma resistance or erosion rate values. For example, a plasma resistant material may have a first plasma resistance or erosion rate associated with a first type of plasma and a second plasma resistance or erosion rate associated with a second type of plasma.

When the terms “about” and “approximately” are used herein, these are intended to mean that the nominal value presented is precise within ±10%. Some embodiments are described herein with reference to chamber components and other articles installed in plasma etchers for semiconductor manufacturing. However, it should be understood that such plasma etchers may also be used to manufacture micro-electro-mechanical systems (MEMS)) devices. Additionally, the articles described herein may be other structures that are exposed to plasma or other corrosive environments. Articles discussed herein may be chamber components for processing chambers such as semiconductor processing chambers. For example, the articles may be chamber components for a plasma etcher, a plasma cleaner, a plasma propulsion system, or other processing chambers. Examples of chamber components that may benefit from embodiments of the invention include a substrate support assembly, an electrostatic chuck (ESC), a ring (e.g., a process kit ring or single ring), a chamber wall, a base, a gas distribution plate, a face plate, a showerhead, a nozzle, a lid, a liner, a liner kit, a shield, a plasma screen, a flow equalizer, a cooling base, a chamber viewport, a chamber lid, and so on.

Moreover, embodiments are described herein with reference to M-O—F layers, components and coatings that cause reduced particle contamination when used in a process chamber for plasma rich processes. However, it should be understood that the M-O—F layers, components and coatings discussed herein may also provide reduced particle contamination when used in process chambers for other processes such as non-plasma etchers, non-plasma cleaners, chemical vapor deposition (CVD) chambers physical vapor deposition (PVD) chambers, plasma enhanced chemical vapor deposition (PECVD) chambers, plasma enhanced physical vapor deposition (PEPVD) chambers, plasma enhanced atomic layer deposition (PEALD) chambers, and so forth. Additionally, the techniques discussed herein with regards to formation of M-O—F layers and coatings are also applicable to articles other than chamber components for processing chambers.

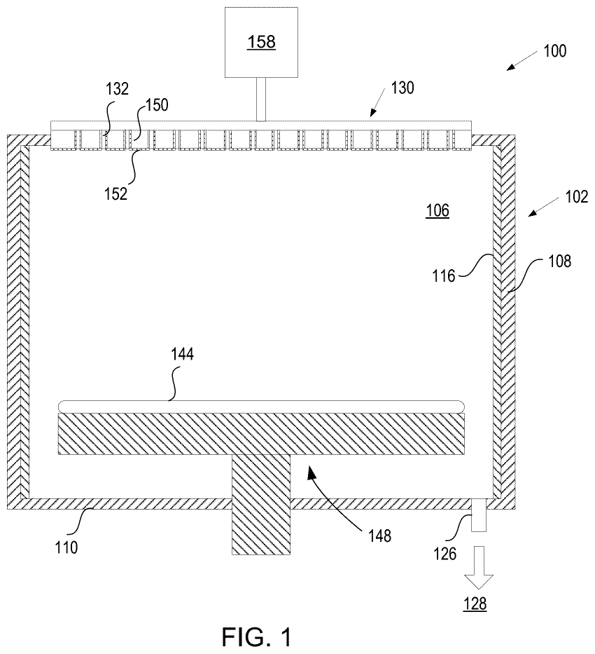

Referring now to the figures, FIG. 1 is a sectional view of a processing chamber 100 (e.g., a semiconductor processing chamber) having one or more chamber components that include a metal oxy-fluoride layer or coating in accordance with embodiments of the present invention. The processing chamber 100 may be used for processes in which a corrosive plasma environment is provided. For example, the processing chamber 100 may be a chamber for a plasma etch reactor (also known as a plasma etcher), a plasma cleaner, and so forth. Examples of chamber components that may be formed of a metal oxy-fluoride or that may include a metal oxy-fluoride layer or coating are a substrate support assembly 148, an electrostatic chuck (ESC), a ring (e.g., a process kit ring or single ring), a chamber wall, a base, a showerhead 130, a gas distribution plate, a liner, a liner kit, a shield, a plasma screen, a flow equalizer, a cooling base, a chamber viewport, a chamber lid, a nozzle, process kit rings, and so on.

In an embodiment, the metal oxy-fluoride component, layer or coating may be formed using a metal oxy-fluoride source material. The metal oxy-fluoride source material may include YF₃, ZrF₄ or combination thereof and a metal oxide. The metal oxide consists of yttrium oxide (Y₂O₃) and zirconium oxide (ZrO₂). The metal oxy-fluoride component, layer or coating may include 35-50 at. % of Y; 0.3-10 at. % of Zr; 5-57 at. % of O; and 3-65 at. % of F. The metal oxy-fluoride component, layer or coating is amorphous in embodiments.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110. Any of the showerhead 130 (or lid and/or nozzle), sidewalls 108 and/or bottom 110 may include the metal oxy-fluoride coating.

An outer liner 116 may be disposed adjacent the sidewalls 108 to protect the chamber body 102. The outer liner 116 may be a halogen-containing gas resist material such as Al₂O₃ or Y₂O₃. The outer layer 116 may be coated with the metal oxy-fluoride coating in some embodiments.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 includes multiple gas delivery holes 132 throughout the showerhead 130. The showerhead 130 may by aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, Cl₂, CCl₄, BCl₃ and SiF₄, among others, and other gases such as O₂, or N₂O. Examples of carrier gases include N₂, He, Ar, and other gases inert to process gases (e.g., non-reactive gases). The fluorine based gases may cause fluoride deposits to buildup on the holes of standard showerheads and/or a contamination layer to form on the holes of the showerheads. However, the holes 132 of showerhead 130 may be resistant to such fluoride buildup because of the metal oxy-fluoride coating 152.

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner (not shown) may cover a periphery of the substrate support assembly 148. The inner liner may be a halogen-containing gas resist material such as Al₂O₃ or Y₂O₃.

Any of the showerhead 130 (or lid and/or nozzle), sidewalls 108, bottom 110, substrate support assembly 148, outer liner 116, inner liner (not shown), or other chamber component may be composed of a metal oxy-fluoride and/or may include a metal oxy-fluoride coating in accordance with embodiments. For example, as shown showerhead 130 includes a metal oxy-fluoride coating 152. In some embodiments, the M-O—F coating is a Y—Zr—O—F coating.

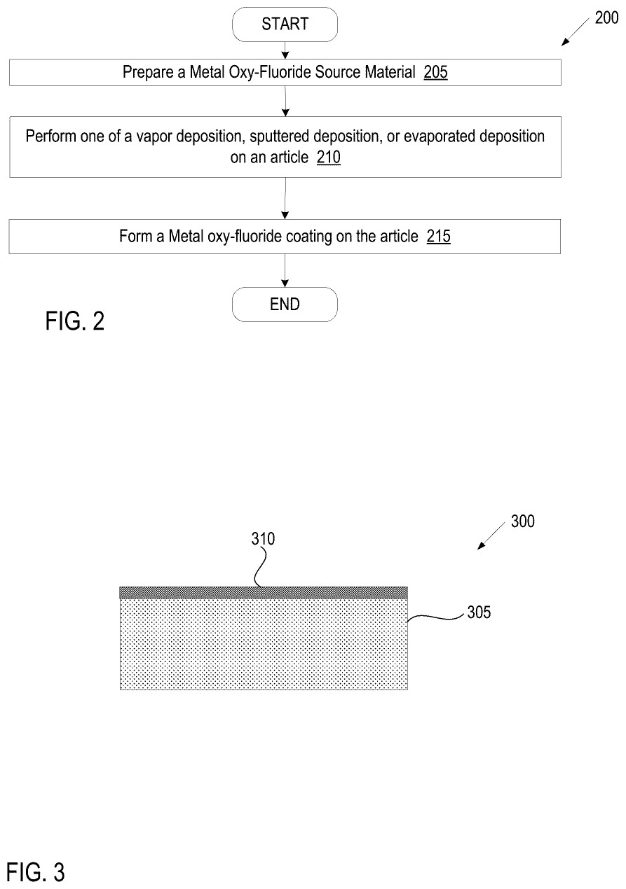

FIG. 2 illustrates a process 200 for applying a coating to a surface of an article according to an embodiment. In some embodiments, the coating may be formed using a metal oxy-fluoride source material. In block 205, the metal oxy-fluoride source material is prepared. In one embodiment, the metal oxy-fluoride source material includes YF₃, ZrF₄, or combination thereof, and a metal oxide. The metal oxide includes Y₂O₃, ZrO₂, or a combination thereof. In one embodiment, to prepare the metal oxy-fluoride source material, the YF₃, ZrF₄ or combination thereof and the metal oxide may include powders or pellets and may be physically mixed together. In another embodiment, to prepare the metal oxy-fluoride source material, the YF₃, ZrF₄, or combination thereof and the metal oxide may include powders or pellets and are thermo-physically fused together by hot pressing or by hot isostatic pressing or by cold isostatic pressing or similar process. In yet another embodiment, the metal fluorides, such as YF₃ or ZrF₄, and oxide materials, such as Y₂O₃ or ZrO₂, may be fused and reacted together via electric arc fusion or electron beam melting or similar process. In some embodiments, the metal oxy-fluoride source material may be heat treated to improve chemical homogeneity of the material. In one embodiment, the metal oxy-fluoride source includes about 5 mol % to about 90 mol % of YF₃, ZrF₄ or combination thereof and about 10 mol % to about 95 mol % of the metal oxide. In some embodiments, the metal oxy-fluoride source material includes about 50 mol % of YF₃, ZrF₄ or combination thereof and about 50 mol % of the metal oxide. In another embodiment, the metal oxy-fluoride source material includes about 90 mol % of YF₃, ZrF₄ or combination thereof and about 10 mol % of the metal oxide. In yet another embodiment, the metal oxy-fluoride source material includes about 5 mol % of YF₃, ZrF₄ or combination thereof and about 95 mol % of the metal oxide. In one embodiment, the metal oxide may include about 90% Y₂O₃ and about 10% ZrO₂ based on total mole percent of the metal oxide. In another embodiment, the metal oxide may include about 95% Y₂O₃ and about 5% ZrO₂ based on total mole percent of the metal oxide. In yet another embodiment, the metal oxide may include about 80%-95% Y₂O₃ and about 5-15% ZrO₂ based on total mole percent of the metal oxide.

After preparing the metal oxy-fluoride source material 205, a deposition or formation process, such as, a vapor deposition, sputtered deposition, or evaporated deposition, is performed to apply the metal oxy-fluoride source material in block 210. The deposition or formation process may include a plasma spray process, atomic layer deposition (ALD), ion assisted deposition (IAD), air plasma spray process, magnetron sputtering, electron beam physical vapor deposition (EBPVD), or thermal evaporation physical vapor deposition, spark plasma sintering, hot pressing, cold isostatic pressing, reverse co-precipitation, or a suspension plasma spray process. The deposition or formation process is performed to form a metal oxy-fluoride coating or bulk material on an article 215.

If APPS is performed, then the metal oxy-fluoride coating may have a thickness of about 100-300 microns and have a porosity of about 2-5%. If SPS is performed, then the metal oxy-fluoride coating may have a thickness of about 25-100 microns and have a porosity of about 0.1-3%. If IAD is performed, then the metal oxy-fluoride coating may have a thickness of about 1-20 microns and have a porosity of less than about 0.1% (e.g., effectively 0%). If ALD is performed, then the metal oxy-fluoride coating may have a thickness of about 10 nm to about 1 micron and have a porosity of about 0%. The metal oxy-fluoride coating is a conformal coating. As used herein the term conformal as applied to a layer means a layer that covers features of an article with a substantially uniform thickness. In one embodiment, conformal layers discussed herein have a conformal coverage of the underlying surface that is coated (including coated surface features) with a uniform thickness having a thickness variation of less than about +/−20%, a thickness variation of +/−10%, a thickness variation of +/−5%, or a lower thickness variation.

In one embodiment, the metal oxy-fluoride coating has about 35-50 at. % of Y; about 0.3-10 at. % of Zr; about 5-57 at. % of O; and about 3-65 at. % of F. The metal oxy-fluoride coating having the described atomic percentage is amorphous. The metal oxy-fluoride coating on the article has a uniform thickness. It has been found that including fluoride in combination with a metal oxide in the source material breaks up the crystalline structure, such that the coating is amorphous. In an alternative method for coating a chamber component,

In an alternative method for coating an article, a metal oxy-fluoride coating is deposited on the surface of a chamber component. The metal oxy-fluoride coating that is deposited, is the same composition as the coating as described above in reference to the metal oxy-fluoride source material of block 205 in FIG. 2. After depositing the metal oxy-fluoride coating, the chamber component may be heated. The metal oxy-fluoride coating may have a thickness of about 10 nm to about 300 μm.

FIG. 3 illustrates a cross sectional side view of a chamber component 300 that includes a metal oxy-fluoride coating 310 according to an embodiment on a body 305 of the chamber component 300. The chamber component 300 may have a metal body (e.g., aluminum or an aluminum alloy such as Al 6061) or a ceramic body (e.g., Al₂O₃, AlN, SiC, etc.). The metal oxy-fluoride coating 310 includes a metal oxy-fluoride having about 35-50 at. % of Y; about 0.3-10 at. % of Zr; about 5-57 at. % of O; and about 3-65 at. % of F. In one embodiment, the metal oxy-fluoride coating 310 is amorphous. As can be seen in FIG. 3, the metal oxy-fluoride coating 310 coats at least one surface of the chamber component 300 for semiconductor processing equipment.

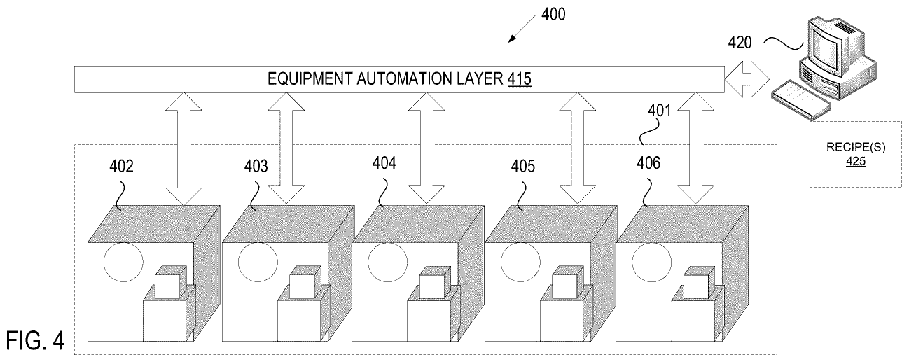

FIG. 4 illustrates an example architecture of a manufacturing system 400. The manufacturing system 400 may be a manufacturing system for applying coatings to articles such as chamber components. In one embodiment, the manufacturing system 400 includes manufacturing machines 401 (e.g., processing equipment) connected to an equipment automation layer 415. The manufacturing machines 401 may include a furnace 402, a wet cleaner 403, a plasma spraying system 404, electron beam physical vapor deposition (EBPVD), evaporative thermal physical vapor deposition, an atomic layer deposition (ALD) system 405, an IAD system 406, a plasma etch reactor (not shown), a bead blaster (not shown), a CVD system (not shown), a plasma cleaner (not shown) and/or another processing chamber the uses a fluorine-based plasma. In some embodiments, the manufacturing machines 401 may also include a polisher, a plating system, a sputtering system, an oxidation system, and/or other machines. The manufacturing system 400 may further include one or more computing device 420 connected to the equipment automation layer 415. In alternative embodiments, the manufacturing system 400 may include more or fewer components. For example, the manufacturing system 400 may include manually operated (e.g., off-line) processing equipment 401 without the equipment automation layer 415 or the computing device 420.

Furnace 402 is a machine designed to heat articles such as ceramic articles. Furnace 402 includes a thermally insulated chamber, or oven, capable of applying a controlled temperature on articles (e.g., ceramic articles) inserted therein. In one embodiment, the chamber is hermitically sealed. Furnace 402 may include a pump to pump air out of the chamber, and thus to create a vacuum within the chamber. Furnace 402 may additionally or alternatively include a gas inlet to pump gasses (e.g., inert gasses such as Ar or N₂ and/or reactive gases such as hydrogen fluoride (HF)) into the chamber. Furnace 202 may be used to perform an HF heat treatment process in embodiments.

Wet cleaner 403 is a cleaning apparatus that clean articles (e.g., articles) using a wet clean process. Wet cleaner 403 includes a wet baths filled with liquids, in which the substrate is immersed to clean the substrate. Wet cleaner 403 may agitate the wet bath using ultrasonic waves during cleaning to improve a cleaning efficacy. This is referred to herein as sonicating the wet bath.

In some embodiments, the wet cleaner 403 include a first wet cleaner that contains deionized (DI) water and a second wet cleaner that contains an acid solid. The acid solution may be a hydrofluoric acid (HF) solution, a hydrochloric acid (HCl) solution, a nitric acid (HNO₃) solution, or combination thereof in embodiments. The acid solution may remove surface contaminants from the article and/or may remove an oxide from the surface of the article. an HF acid solution. In one embodiment, an acid solution containing approximately 0.05-50 vol % HF and 50-95 vol % water is used. In one embodiment, an acid solution containing about 0.05-1.0 (or 0.05-0.1) vol % HF, 99.5-99.95 vol. % and an amount of ammonium fluoride as a buffering agent is used.

The wet cleaner 403 may clean articles at multiple stages during processing. For example, wet cleaner 403 may clean an article after a substrate has been polished, before performing plating (e.g., electroplating), before forming a coating, and so on.

In other embodiments, alternative types of cleaners such as dry cleaners may be used to clean the articles. Dry cleaners may clean articles by applying heat, by applying gas, by applying plasma, and so forth.

Plasma spraying system 404 is a machine configured to plasma spray a coating to the surface of an article. Plasma spraying system 404 may be a low pressure plasma spraying (LPPS) system or an atmospheric pressure plasma spraying (APPS) system. Both LPPS systems and APPS systems may be used to deposit a porous, low density plasma resistant layer (e.g., a second plasma resistant layer for a multi-layer plasma resistant coating). An LPPS system includes a vacuum chamber that can be pumped down to reduced pressure (e.g., to a vacuum of 1 Mbar, 10 Mbar, 35 Mbar, etc.), while an APPS system does not include any vacuum chamber, and may instead include an open chamber or room.

In a plasma spraying system 404, an arc is formed between two electrodes through which a gas is flowing. As the gas is heated by the arc, the gas expands and is accelerated through a shaped nozzle of a plasma torch, creating a high velocity plasma jet. Powder composed of a ceramic and/or metal material is injected into the plasma jet by a powder delivery system. An intense temperature of the plasma jet melts the powder and propels the molten ceramic and/or metal material towards an article. Upon impacting with the article, the molten powder flattens, rapidly solidifies, and forms a layer of a ceramic coating that adheres to the article. The parameters that affect the thickness, density, and roughness of the plasma sprayed layer include type of powder, powder size distribution, powder feed rate, plasma gas composition, gas flow rate, energy input, pressure, and torch offset distance. Alternatively, suspension plasma spray (SPS) may be performed and the powder may be dispersed in a liquid suspension before being injected into the plasma jet. The plasma sprayed layer may have a porosity of about 2-5% in embodiments. Porosity is a measure of a void (e.g., empty space) in a material, and is a fraction of the volume of voids over the total volume or the material.

ALD system 405 is a system that performs atomic layer deposition to form a thin dense conformal layer on an article. ALD allows for a controlled self-limiting deposition of material through chemical reactions with the surface of the article. Aside from being a conformal process, ALD is also a uniform process. All exposed sides of the article, including high aspect ratio features (e.g., about 10:1 to about 300:1) will have the same or approximately the same amount of material deposited. A typical reaction cycle of an ALD process starts with a precursor (i.e., a single chemical A) flooded into an ALD chamber and adsorbed onto the surface of the article in a first half reaction. The excess precursor is then flushed out of the ALD chamber before a reactant (i.e., a single chemical R) is introduced into the ALD chamber for a second half reaction and subsequently flushed out. This process may be repeated to build up an ALD layer having a thickness of up to about 1 micron in some embodiments.

Unlike other techniques typically used to deposit coatings on articles, such as plasma spray coating and ion assisted deposition, the ALD technique can deposit a layer of material within high aspect ratio features (i.e., on the surfaces of the features). Additionally, the ALD technique produces relatively thin (i.e., 1 μm or less) coatings that are porosity-free (i.e., pin-hole free). The term “porosity-free” as used herein means absence of any pores, pin-holes, or voids along the whole depth of the coating as measured by transmission electron microscopy (TEM).

A CVD system performs chemical vapor deposition (CVD). CVD is a chemical process in which an article is exposed to one or more volatile precursors that react with and/or decompose onto the article to form a layer (e.g., to form a metal oxy-fluoride (Y—Zr—O—F) layer).

The EB-IAD system 406 is a system that performs electron beam ion assisted deposition. Alternatively, other types of IAD systems may be used in embodiments, such as activated reactive evaporation ion assisted deposition (ARE-IAD) or ion beam sputtering ion assisted deposition (IBS-IAD). EB-IAD may be performed by evaporation. IBS-IAD may be performed by sputtering a solid target material (e.g., a solid metal target). Any of the IAD methods may be performed in the presence of a reactive gas species, such as O₂, N₂, halogens, etc.

For the various types of IAD, a thin film plasma resistant layer is formed by an accumulation of deposition materials in the presence of energetic particles such as ions. The deposition materials include atoms, ions, radicals, or their mixture. The energetic particles may impinge and compact the thin film plasma resistant layer as it is formed.

For IAD, a material source provides a flux of deposition materials while an energetic particle source provides a flux of the energetic particles, both of which impinge upon an article throughout the IAD process. The energetic particle source may be an oxygen or other ion source. The energetic particle source may also provide other types of energetic particles such as radicals, atoms, ions, and nano-sized particles which come from particle generation sources (e.g., from plasma, reactive gases or from the material source that provide the deposition materials). The material source (e.g., a target body) used to provide the deposition materials may be a bulk sintered ceramic corresponding to the same ceramic that the plasma resistant layer is to be composed of.

IAD may utilize one or more plasmas or beams to provide the material and energetic ion sources. Reactive species may also be provided during deposition of the plasma resistant coating. With IAD processes, the energetic particles may be controlled by the energetic ion (or other particle) source independently of other deposition parameters. The energy (e.g., velocity), density and incident angle of the energetic ion flux may be selected to achieve a target composition, structure, crystalline orientation and grain size of the plasma resistant layer. Additional parameters that may be adjusted are a temperature of the article during deposition as well as the duration of the deposition. EB-IAD and IBS-IAD depositions are feasible on a wide range of surface conditions. However, IAD performed on polished surfaces may achieve increased breakdown voltages.

The equipment automation layer 415 may interconnect some or all of the manufacturing machines 401 with computing devices 420, with other manufacturing machines, with metrology tools and/or other devices. The equipment automation layer 415 may include a network (e.g., a location area network (LAN)), routers, gateways, servers, data stores, and so on. Manufacturing machines 401 may connect to the equipment automation layer 415 via a SEMI Equipment Communications Standard/Generic Equipment Model (SECS/GEM) interface, via an Ethernet interface, and/or via other interfaces. In one embodiment, the equipment automation layer 415 enables process data (e.g., data collected by manufacturing machines 401 during a process run) to be stored in a data store (not shown). In an alternative embodiment, the computing device 220 connects directly to one or more of the manufacturing machines 201.

In one embodiment, some or all manufacturing machines 401 include a programmable controller that can load, store and execute process recipes. The programmable controller may control temperature settings, gas and/or vacuum settings, time settings, etc. of manufacturing machines 401. The programmable controller may include a main memory (e.g., read-only memory (ROM), flash memory, dynamic random access memory (DRAM), static random access memory (SRAM), etc.), and/or a secondary memory (e.g., a data storage device such as a disk drive). The main memory and/or secondary memory may store instructions for performing heat treatment processes described herein.

The programmable controller may also include a processing device coupled to the main memory and/or secondary memory (e.g., via a bus) to execute the instructions. The processing device may be a general-purpose processing device such as a microprocessor, central processing unit, or the like. The processing device may also be a special-purpose processing device such as an application specific integrated circuit (ASIC), a field programmable gate array (FPGA), a digital signal processor (DSP), network processor, or the like. In one embodiment, programmable controller is a programmable logic controller (PLC).

In one embodiment, the manufacturing machines 401 are programmed to execute recipes that will cause the manufacturing machines to heat treat an article, coat an article, and so on. In one embodiment, the manufacturing machines 401 are programmed to execute process recipes 425 that perform operations of a multi-step process for manufacturing an article or coating, as described with reference to FIG. 2. In one embodiment, one or more of the manufacturing machines 401 are programmed to execute a process recipe for a process to apply a metal oxy-fluoride source material to protect chamber components prior to performing a process recipe that uses a plasma to process a substrate, as described with reference to FIG. 2. The computing device 420 may store one or more process recipes 425 that can be downloaded to the manufacturing machines 401 to cause the manufacturing machines 401 to manufacture articles in accordance with embodiments of the present invention.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should be determined with reference to the appended claims, along with the full scope of equivalents to which such claims are entitled.

1. A method comprising:
providing a metal oxy-fluoride source material comprising YF₃, ZrF₄ or combination thereof and a metal oxide consisting of yttrium oxide (Y₂O₃) and zirconium oxide (ZrO₂), wherein the metal oxy-fluoride source material includes 5 mol % to 90 mol % of YF₃, ZrF₄ or combination thereof and 10 mol % to 95 mol % of the metal oxide; and
performing one of a vapor deposition, sputtered deposition or evaporated deposition of the metal oxy-fluoride source material to form a metal oxy-fluoride coating on an article, the metal oxy-fluoride coating having:
$$35 - 50 at . \% of yttrium ( Y ) ;$$
$$0.3 - 10 at . \% of zirconium ( Zr ) ;$$
$$5 - 57 at . \% of oxygen ( O ) ; and$$
$$3 - 65 at . \% of fluorine ( F ) ;$$
wherein the metal oxy-fluoride coating is amorphous.

2. The method of claim 1, wherein the metal oxy-fluoride source material includes 50 mol % of YF₃, ZrF₄ or combination thereof and 50 mol % of the metal oxide.

3. The method of claim 2, wherein the metal oxide comprises 90% Y₂O₃ and 10% ZrO₂, based on total mole percent of the metal oxide.

4. The method of claim 2, wherein the metal oxide comprises 95% Y₂O₃ and 5% ZrO₂, based on total mole percent of the metal oxide.

5. The method of claim 1, wherein the metal oxy-fluoride source material includes 90 mol % of YF₃, ZrF₄ or combination thereof and 10 mol % of the metal oxide.

6. The method of claim 5, wherein the metal oxide comprises 90% Y₂O₃ and 10% ZrO₂, based on total mole percent of the metal oxide.

7. The method of claim 1, wherein the metal oxy-fluoride source material includes 5 mol % of YF₃, ZrF₄ or combination thereof and 95 mol % of the metal oxide.

8. The method of claim 7, wherein the metal oxide comprises 90% Y₂O₃ and 10% ZrO₂, based on total mole percent of the metal oxide.

9. (canceled)

10. The method of claim 1, wherein the metal oxy-fluoride coating consists of a Y—Zr—O—F layer.

11. A thin film comprising:
a metal oxy-fluoride having:
$$35 - 50 at . \% of yttrium ( Y ) ;$$
$$0.3 - 10 at . \% of zirconium ( Zr ) ;$$
$$5 - 57 at . \% of oxygen ( O ) ; and$$
$$3 - 65 at . \% of fluorine ( F ) ;$$
wherein the thin film is amorphous.

12. The thin film of claim 11, wherein the thin film coats at least one surface of a chamber component for semiconductor processing equipment.

13. A process comprising:
depositing a metal oxy-fluoride coating on a surface of a chamber component, the metal oxy-fluoride coating comprising yttrium fluoride (YF₃) or zirconium fluoride (ZrF₄) and a metal oxide consisting of yttrium oxide (Y₂O₃) and zirconium oxide (ZrO₂) having 5 mol % to 90 mol % of YF₃ or ZrF₄ and 10 mol % to 95 mol % of the metal oxide;
wherein the metal oxy-fluoride coating is amorphous.

14. The process of claim 13, further comprising heating the chamber component to within a temperature range of about 600-1400° C.

15. The process of claim 13, wherein the metal oxy-fluoride coating has
$$35 - 50 at . \% of yttrium ( Y ) ;$$
$$0.3 - 10 at . \% of zirconium ( Zr ) ;$$
$$5 - 57 at . \% of oxygen ( O ) ; and$$
$$3 - 65 at . \% of fluorine ( F ) .$$

16. (canceled)

17. (canceled)

18. (canceled)

19. The process of claim 13, wherein depositing the metal oxy-fluoride coating comprises performing one of:
performing a plasma spray process to deposit the metal oxy-fluoride coating;
performing atomic layer deposition (ALD) to deposit the metal oxy-fluoride coating;
performing ion assisted deposition (IAD) to deposit the metal oxy-fluoride coating;
performing electron beam physical vapor deposition (EBPVD) to deposit the metal oxy-fluoride coating;
performing thermal evaporative physical vapor deposition to deposit the metal oxy-fluoride coating;
performing an air plasma spray process to deposit the metal oxy-fluoride coating;
performing a magnetron sputtering to deposit the metal oxy-fluoride coating;
performing a spark plasma sintering to deposit the metal oxy-fluoride coating;
performing a hot pressing to deposit the metal oxy-fluoride coating;
performing a cold isostatic pressing to deposit the metal oxy-fluoride coating;
performing a co-evaporation physical vapor deposition process to deposit the metal oxy-fluoride coating;
performing a reverse co-precipitation to deposit the metal oxy-fluoride coating; or
performing a suspension plasma spray process to deposit the metal oxy-fluoride coating.

20. The process of claim 13, wherein the metal oxy-fluoride coating has a thickness of about 10 nm to about 300 μm.

21. A method comprising:
providing a metal fluoride source material comprising YF₃, ZrF₄ or combination thereof and a metal oxide source material comprising yttrium oxide (Y₂O₃) and zirconium oxide (ZrO₂), wherein the metal oxide source material includes 0.1 mol % to 20 mol % of ZrO₂; and
performing one of a vapor deposition, sputtered deposition or evaporated deposition of the metal fluoride source material while concurrently and independently performing one of a vapor deposition, sputtered deposition or evaporated deposition of the metal oxide source material to form a metal oxy-fluoride coating on an article, wherein the respective evaporation and deposition rates from the metal fluoride source material and the metal oxide source material produce the metal oxy-fluoride coating having:
$$35 - 50 at . \% of yttrium ( Y ) ;$$
$$0.3 - 10 at . \% of zirconium ( Zr ) ;$$
$$5 - 57 at . \% of oxygen ( O ) ; and$$
$$3 - 65 at . \% of fluorine ( F ) ;$$
wherein the metal oxy-fluoride coating is amorphous.

22. The method of claim 21, wherein the respective deposition rates of the metal fluoride source material and the metal oxide source material form a combined deposited flux including about 50 mol % of YF₃, ZrF₄ or combination thereof and about 50 mol % of the metal oxide.

23. (canceled)

24. (canceled)

25. The method of claim 21, wherein the respective deposition rates of the metal fluoride source material and the metal oxide source material form a combined deposited flux including about 90 mol % of YF₃, ZrF₄ or combination thereof and about 10 mol % of the metal oxide.

26. (canceled)

27. The method of claim 21, wherein the respective deposition rates of the metal fluoride source material and the metal oxide source material form a combined deposited flux including about 5 mol % of YF₃, ZrF₄ or combination thereof and about 95 mol % of the metal oxide.

28. (canceled)

29. (canceled)

30. (canceled)
